(19) United States
(12) Patent Application Publication
(10) Pub. No.: US 2017/0064830 A1
(43) Pub. Date: Mar. 2, 2017

(54) Circuit Assembly for Compact Acoustic Device

(71) Applicant: Motorola Mobility LLC, Chicago, IL (US)

(72) Inventors: Peng Jiang, Duluth, GA (US); Martin H. Ramsden, Lawrenceville, GA (US); Marc B. Riley, Grayson, GA (US); Ryan P. Rye, Lawrenceville, GA (US)

(21) Appl. No.: 14/833,494

(22) Filed: Aug. 24, 2015

(51) Int. Cl. H05K 1/14

(52) U.S. Cl. CPC H05K 1/147

(57) ABSTRACT

A unitary printed circuit board assembly includes a circuit board and a flexible substrate extending from, and continuous with, the circuit board. The flexible substrate includes a first portion extending from the circuit board and terminating a second portion. The second portion of the flexible substrate can be wrapped about a spring form. The assembly can be disposed in a housing defining a body and an ear insertion stem, with the spring form disposed within the ear insertion stem with arms of the spring form applying a biasing force against inner surfaces of the ear insertion stem.

### BACKGROUND

Technical Field

This disclosure relates generally to electronic devices, and more particularly to circuit assemblies disposed within electronic devices.

Background Art

Wireless headsets are commonly used with many portable electronic devices. For example, wireless headsets can be used with a smartphone that includes a multimedia player, such as an MPEG-3 music player, to listen to music. Modern headsets take many forms, including over the ear clip on devices and over the head headphones. The most compact headsets are manufactured as “in the ear” or “in the ear canal” earbuds. Earbuds generally include small speakers and fit into either the folds of the human ear or into the ear canal itself.

Advanced control functions are available in wireless headsets when they include sophisticated electronic components such as infrared sensors. Illustrating by example, infrared sensors emit an electromagnetic field. A receiver then receives reflections of the field from a nearby object, such as a user's ear. The wireless headset can employ such sensors to manage audio output. For instance, when a sensor detects that the wireless headset is inserted into an ear, the headset may activate the loudspeaker. However, when the wireless headset is removed from the ear, as detected by the infrared sensor, circuitry may be placed into a low-power or sleep mode.

To work properly, the transmitter emitting the electromagnetic field needs to be located where the sensor can easily receive reflected signals. However, for an earbud to provide the best sound, the loudspeaker needs to be properly placed within the headset. Sometimes the need to place the transmitter where reflected signals can be easily received and the need to place the loudspeaker for optimum acoustic performance collide. It can be difficult to optimally locate both components without creating acoustic interference. This problem is compounded by the desire to make “ear bud” style headsets as small as possible. Fashion conscious users may be reluctant to use a large earpiece that resembles a vintage hearing aid. This desire to make earbuds smaller, while still providing satisfactory acoustic performance and adding advanced functionality with infrared sensors, creates a tension in that it simply becomes difficult to “fit” all the electronic components necessary for proper acoustic performance into a package that fits within a user's ear canal. This is especially true given the requirement that any wireless earbud also include a battery as an energy source. It would be advantageous to have an improved circuit assembly that allows earbuds to become smaller without compromising acoustic performance.

### BRIEF DESCRIPTION OF THE DRAWINGS

FIG. 1 illustrates one explanatory circuit assembly in accordance with one or more embodiments of the disclosure.

FIG. 2 illustrates a partial view of another explanatory circuit assembly in accordance with one or more embodiments of the disclosure.

FIG. 3 illustrates an exploded view of an explanatory apparatus in accordance with one or more embodiments of the disclosure.

FIG. 4 illustrates one explanatory spring device in accordance with one embodiment of the disclosure.

FIG. 5 illustrates another view of one explanatory spring device in accordance with one embodiment of the disclosure.

FIG. 6 illustrates a partial view of one explanatory circuit assembly, when partially assembled, in accordance with one or more embodiments of the disclosure.

FIG. 7 illustrates a partial view of one explanatory circuit assembly, when a flexible substrate is assembled about a spring member, in accordance with one or more embodiments of the disclosure.

FIG. 8 illustrates a partial view of an ear bud housing having one explanatory circuit assembly disposed therein in accordance with one or more embodiments of the disclosure.

FIG. 9 illustrates another partial view of an ear bud housing having one explanatory circuit assembly disposed therein in accordance with one or more embodiments of the disclosure.

FIG. 10 illustrated an exploded view of one explanatory apparatus in accordance with one or more embodiments of the disclosure.

FIG. 11 illustrates one explanatory apparatus in accordance with one or more embodiments of the disclosure.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present disclosure.

### DETAILED DESCRIPTION OF THE DRAWINGS

Before describing in detail embodiments that are in accordance with the present disclosure, it should be observed that the embodiments reside primarily in combinations of method steps and apparatus components related to improving audio performance in an audio device. Alternate implementations are included, and it will be clear that functions may be executed out of order from that shown or discussed, including substantially concurrently or in reverse order, depending on the functionality involved. Accordingly, the apparatus components and method steps have been represented where appropriate by conventional symbols in the drawings, showing only those specific details that are pertinent to understanding the embodiments of the present disclosure so as not to obscure the disclosure with details that will be readily apparent to those of ordinary skill in the art having the benefit of the description herein.

Embodiments of the disclosure are now described in detail. Referring to the drawings, like numbers indicate like parts throughout the views. As used in the description herein and throughout the claims, the following terms take the meanings explicitly associated herein, unless the context clearly dictates otherwise: the meaning of “a,” “an,” and “the” includes plural reference, the meaning of “in” includes “in” and “on.” Relational terms such as first and second, top and bottom, and the like may be used solely to distinguish one entity or action from another entity or action without necessarily requiring or implying any actual such relationship or order between such entities or actions. Also, reference designators shown herein in parenthesis indicate components shown in a figure other than the one in discussion. For example, talking about a device (10) while discussing figure A would refer to an element, 10, shown in figure other than figure A.

Embodiments of the disclosure provide a wireless earbud accessory that is sufficiently compact as to seat flush or below the outer surface/end of the tragus portion of the ear. This low profile insertion capability is unlike prior art headsets, which have portions seating well above the tragus, and that are always visible to others. While some prior art hearing aids and professional wired ear speakers sit below the tragus, these devices do not include wireless communication capability. Wireless communication circuits, including antennas, shields, transceivers, and so forth, require a relatively large amount of space within a device. Advantageously, the printed circuit board assemblies of the present disclosure are sufficiently compact as to provide a below-tragus earbud with wireless communication capabilities.

Embodiments of the disclosure provide a circuit assembly that minimizes volume required for the printed circuit board assembly and related components. Embodiments of the disclosure further optimize a physical arrangement of these components to achieve optimal wireless performance, e.g., optimal radio frequency antenna gain and so forth. Moreover, embodiments of the disclosure additionally optimize the location, arrangement, and spacing of other electronic components, such as proximity sensors. This optimization of location of components other than acoustic components, e.g., infrared sensors, advantageously occurs without reducing optimal acoustic performance when a spring device or spring member configured in accordance with embodiments of the disclosure is used.

In one or more embodiments, a circuit assembly for use in an acoustic ear bud includes a printed circuit board assembly. In one embodiment, the printed circuit board assembly comprises a circuit board with a flexible substrate extending from, and being continuous with, the circuit board. In one embodiment, the flexible substrate comprises an extension portion terminating at a capital portion. The capital portion can be oriented transverse with the extension portion in one or more embodiments. For example, in one illustrative embodiment the extension portion and the capital portion define an inverse “T” shape extending from the circuit board.

In one embodiment, the circuit assembly further includes a spring member. The spring member can be constructed by forming a material, such as a springy metal, into a spring form. For example, in one embodiment the spring form has a triangular cross section with one corner defining a non-intersecting corner to allow a first spring arm and second spring arm extending from a base member to deflect when the spring form is inserted into an ear canal insertion stem of the housing.

In one embodiment, the capital portion of the flexible substrate is wrapped about the spring member. In one embodiment, the spring member is formed to define an acoustic channel through which acoustic energy can pass. When the capital portion of the flexible substrate is wrapped about the spring member and the resulting assembly is inserted into an ear canal insertion stem of a housing, ends of any of the base member, first spring arm, or second spring arm can cause those elements to deflect such that the spring member applies a biasing force against internal surfaces of the ear canal insertion stem. This biasing and deflecting action causes the acoustic channel to expand, thereby allowing acoustic energy from an acoustic driver disposed on one side of the spring member to pass through the acoustic channel to a port of the ear canal insertion stem.

In one embodiment, the capital portion of the flexible substrate defines a first major face and a second major face. In one embodiment, the first major face is disposed adjacent to sides of the spring member. For example, in one embodiment the first major face can be adhesively coupled to the sides of the spring member.

In one or more embodiments, one or more electronic circuits can then be disposed on the second major face. For example, in one or more embodiments a circuit assembly includes one or more of an infrared sensor or a temperature sensor to automatically detect when a device is inserted into a user's ear canal. By detecting insertion from temperature or touch, embodiments of the disclosure can activate the device when inserted into the ear and deactivate the device once removed from the ear. In one embodiment, this infrared sensor or temperature sensor can be disposed along the second major face of the capital portion of the flexible substrate. This allows the infrared sensor or temperature sensor to be disposed within the ear canal insertion stem for optimal detection of when the ear bud is disposed within an ear. At the same time, the use of the spring member ensures that no acoustic energy blockage occurs, thereby achieving optimal acoustic performance as well.

In one or more embodiments, the circuit assembly includes a printed circuit board and a flexible substrate that extends from, and is continuous with, the circuit board. A second circuit board and a second flexible substrate interspersed with, and continuous with, the first circuit board. This continuous “board-flex” and/or “board-flex-board” construction allows the components of the circuit assembly to wrap about other components. For example, the capital portion of the flexible substrate extending from the circuit board can wrap about the spring member as described above. Where the second flexible substrate and second circuit board are included, these components and the first circuit board can wrap about a rechargeable battery without using any connectors or jumpers. The result of either construction is a compact circuit assembly offering long device run time. Despite accommodating such a large cell, the continuous nature of the printed circuit board assembly eliminates the need for connectors to interconnect the flexible substrate between the printed circuit boards. The same is true with reference to the infrared sensor or temperature sensor—no connectors are required. This construction results in a more compact assembly that still ensures user comfort when earbud is positioned in the ear bowl or concha. Embodiments of the disclosure further provide the advantages listed above at a relatively low manufacturing cost. The cost is reduced due to the fact that the various components are simple to assemble due to the overall design of the device and component placement.

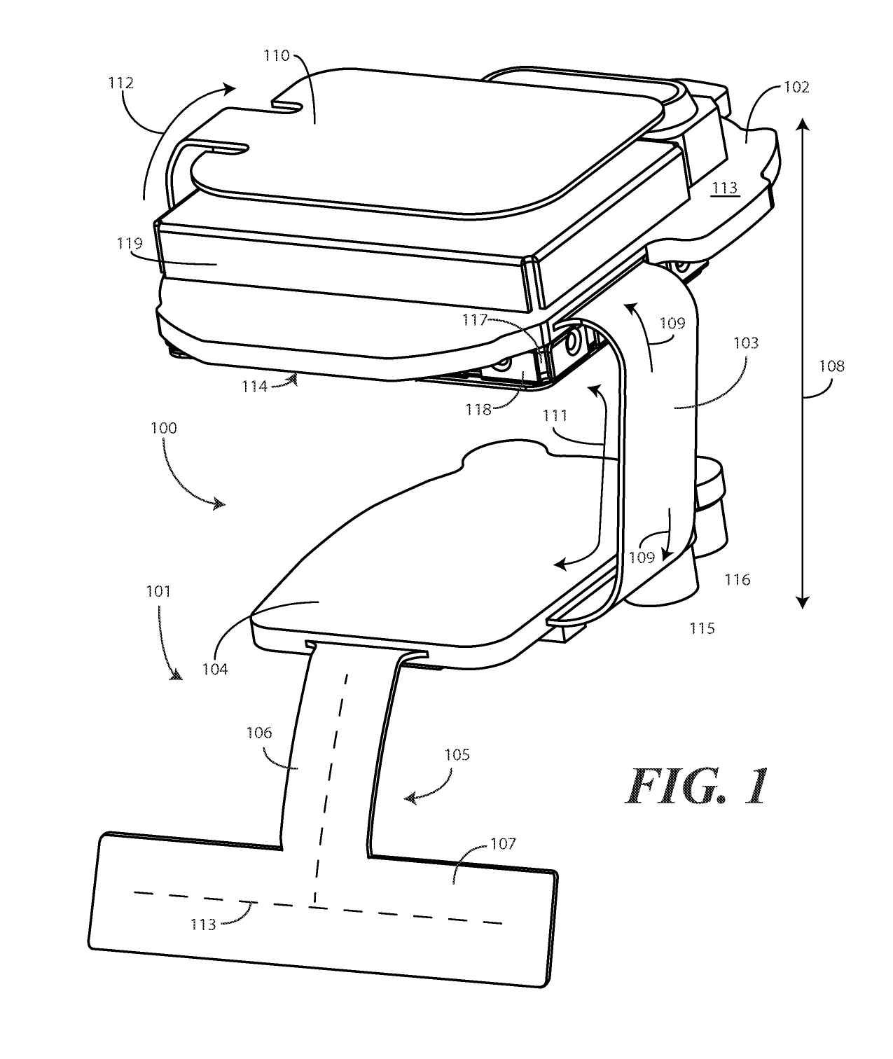

Turning now to FIG. 1, illustrated therein is one explanatory circuit assembly 100 configured in accordance with one or more embodiments of the disclosure. The explanatory circuit assembly 100 of FIG. 1 includes a printed circuit board assembly 101, a flexible substrate 103, and a second circuit board 102. The flexible substrate 103 and the second circuit board 102 are optional. However, their inclusion allows the circuit assembly 100 to be used in an ear bud-style wireless headset while remaining reduced to a compact size such that fashion conscious users will find the ear bud attractive and easy to use.

In this illustrative embodiment, the printed circuit board assembly 101 comprises a printed circuit board 104 and a flexible substrate 105 extending from, and continuous with, the printed circuit board 104. In one embodiment, the flexible substrate 105 defines an extension portion 106 that terminates in a capital portion 107. Here, the extension portion 106 defines a rectangle having its major axis extending away from the printed circuit board 104. The capital portion 107 defines a second rectangle having its major axis oriented transverse with the major axis of the rectangle of the extension portion 106. Accordingly, this flexible substrate 105 defines an inverted T-shape, with the extension portion 106 defining the base of the inverted T and the capital portion 107 defining the top—or bottom due to inversion—of the T. It should be noted that the flexible substrate 105 could take other shapes as well. For example, in another embodiment the flexible substrate 105 is configured as a triangle. In another embodiment, the flexible substrate 105 can have concave or convex side portions that extend outwardly from the printed circuit board 104 to a wider base. Other shapes will be obvious to those of ordinary skill in the art having the benefit of this disclosure.

In one embodiment, each of the printed circuit board 104 and the second circuit board 102 is manufactured from multiple layers. Some layers can be selectively placed conductive metal, such as copper or aluminum, while other layers can be insulative. Insulative layers can be manufactured from fiberglass, FR4, or other materials. In one or more embodiments, each of the printed circuit board 104 and the second circuit board 102 comprises a fiberglass printed circuit board. In another embodiment, each of the printed circuit board 104 and the second circuit board 102 is a FR4 printed circuit board.

In one embodiment, the flexible substrate 105 extends from, and is continuous with, the printed circuit board 104. The flexible substrate 105 can be manufactured as a continuous component extending from the printed circuit board 104 in a variety of ways. Illustrating by example, in one embodiment the printed circuit board 104 and flexible substrate 105 can be manufactured as a single, contiguous, unitary circuit board. The conductive and insulative layers of the single, contiguous, unitary circuit board can then be selectively removed along the flexible substrate 105 until only a single layer of conductive metal from one of the internal layers remains. Insulative material, such as insulative tape, can then be placed about the single layer of conductive metal to form the flexible substrate 105.

Making the flexible substrate 105 continuous with the printed circuit board 104 eliminates the need for connectors to be disposed along the printed circuit board 104 for connection to a prior art flexible substrate. This results in more surface area along each of the printed circuit board 104 and the flexible substrate 105 for electronic components.

Where the second circuit board 102 is included, a second flexible substrate 103 can be interposed between, and is continuous with, the printed circuit board 104 of the circuit assembly 100. The second flexible substrate 103, like flexible substrate 105, can be manufactured as a continuous component of the circuit assembly 100 in a variety of ways. Illustrating by example, in one embodiment the printed circuit board 104 and the second circuit board 102 can be manufactured as a single, contiguous, unitary circuit board. The conductive and insulative layers of the single, contiguous, unitary circuit board can then be selectively removed along the second flexible substrate 103 until only a single layer of conductive metal from one of the internal layers remains. Insulative material, such as insulative tape, can then be placed about the single layer of conductive metal to form the second flexible substrate 103. As with the flexible substrate 105 extending from the printed circuit board 104, making flexible substrates continuous with the printed circuit boards eliminates the need for connectors. In the case of the second circuit board 102 and the second flexible substrate 103, this reduces the overall “stack-up” height 108 of the circuit assembly 100.

The inclusion of the second flexible substrate 103 as a continuous element between the printed circuit board 104 and the second circuit board 102 advantageously allows the circuit assembly 100 to fold or otherwise be wrapped around components. For example, the printed circuit board 104, the second circuit board 102, and the second flexible substrate 103 of circuit assembly 100 of FIG. 1 can be folded 109 to form a “C” shape. In one embodiment this “foldability” allows the printed circuit board 104, the second circuit board 102, and the second flexible substrate 103 of circuit assembly 100 to wrap about a rechargeable battery.

In this illustrative embodiment, the circuit assembly 100 also includes third flexible substrate 110. In one embodiment, as was the case with the second flexible substrate 103 and flexible substrate 105, the third flexible substrate 110 is continuous with a printed circuit board. For example, in one embodiment the third flexible substrate 110 extends from, and is continuous with, the second circuit board 102. (Recall from above that relational terms, such as first and second, top and bottom, and the like, may be used solely to distinguish one entity or action from another entity or action without necessarily requiring or implying any actual such relationship or order between such entities or actions.) In one embodiment, the third flexible substrate 110 is manufactured in the same manner as was the second flexible substrate 103, namely, by selectively removing layers from a single, contiguous, unitary circuit board until only a single layer of conductive metal from one of the internal layers remains, and then covering that layer with insulative tape or other insulating material.

As will be described in more detail below, in one embodiment the third flexible substrate 110 can be folded back over the second circuit board 102. In the illustrative embodiment of FIG. 1 the third flexible substrate 110 is folded back atop the second circuit board 102. This allows the third flexible substrate 110 to define the top of the circuit assembly 100 when the second circuit board 102 is disposed above the printed circuit board 104. Advantageously, in one or more embodiments the third flexible substrate 110 can be used as a touch sensor disposed along the outermost portion of an earbud when the earbud is disposed within a user's ear.

By placing the third flexible substrate 110 just beneath a surface of a housing of an electronic device, in one embodiment a touch sensitive surface may be created along the housing. The user can then control the device by interfacing with the touch sensitive surface, thereby eliminating the need for buttons or other controls that, when actuated, may move the earbud within the user's ear. Placing the touch sensitive surface on a surface of the device provides for simpler user operation in one embodiment.

The third flexible substrate 110 can define a touch sensor in one of a variety of ways. In one or more embodiments, the third flexible substrate 110 defines a capacitive touch-sensing surface. The capacitive touch-sensitive surface can be configured to detect movement of, for example, a user's finger, occurring within a region defined by, for example, the outer perimeter of the third flexible substrate 110. In one embodiment, the third flexible substrate 110 can comprise a first conductor or a first plurality of conductors and a second conductor or second plurality of conductors. These conductors can then cross over each other to define a grid of pixels (where only two conductors are used the third flexible substrate 110 will define a single, large pixel forming a grid of one pixel). One conductor or set of conductors can be coupled to a touch driver, operable with a control circuit, which delivers a signal to each pixel of the grid. Electrical charges then travel to the pixel(s) of the grid. Electromagnetic fields are then created about the pixel(s). The fields are altered by interaction of a user's finger or other conductive object interacting with the third flexible substrate 110. This alteration allows the control circuit to detect touch input.

In one embodiment, where multiple pixels are used, the electrodes defining each pixel along the third flexible substrate 110 can define a coordinate plane. Said differently, each pixel can correspond to a different a particular geographic coordinate along the third flexible substrate 110. By detecting a change in the capacitance of one or more pixels, the control circuit can thus determine an X and Y coordinate at which the touch input occurs. This locational information can be used to control data the device, such as to deliver volume up or volume down information. Other forms of touch-sensitive surfaces disposed along the third flexible substrate 110 for use with embodiments of the disclosure will be obvious to those of ordinary skill in the art having the benefit of this disclosure.

While a capacitive touchpad is one technology suitable for use with the third flexible substrate 110, those of ordinary skill in the art having the benefit of this disclosure will understand that other technologies can be used as well. For example, the third flexible substrate 110 can detect touch, in one or more embodiments, using a surface acoustic wave touch sensor, a surface capacitance sensor, a projected capacitance sensor, a mutual capacitance sensor, a self-capacitance sensor, an infrared grid sensor, an infrared acrylic projection sensor, an optical imaging sensor, a dispersive signal sensor, an acoustic pulse recognition sensor, and so forth.

As noted above, the inclusion of the second flexible substrate 103 and the third flexible substrate 110 advantageously allows the circuit assembly 100 to be folded along each flexible substrate. In the illustrative embodiment of FIG. 1, the third flexible substrate 110 is folded back atop the second circuit board 102. Accordingly, in FIG. 1, the printed circuit board assembly is folded in an “S” shape defined by C shape 111 and reverse C shape 112. This occurs while the inverted T-shape 121 dangles from printed circuit board 104. Other geometric configurations achievable by folding the various components will be obvious to those of ordinary skill in the art having the benefit of this disclosure. It should be noted that any number of flexible substrates can extend from, or be interposed between, the printed circuit board 104 and the second circuit board 102.

In one embodiment, the printed circuit board 104 and the second circuit board 102 each define a first major face and a second major face. For example, the second circuit board 102 defines first major face 113 and second major face 114. The printed circuit board 104 similarly defines a first major face and a second major face. In one embodiment, a plurality of electrical components, e.g., electronic components, can be disposed on one or more of the first major face of the printed circuit board 104, the second major face of the first circuit board, the first major face 113 of the second circuit board 102, the second major face 114 of the second circuit board 102, or combinations thereof.

In one embodiment, at least one electronic component comprises a control circuit 117. In FIG. 1, the control circuit 117 is disposed beneath a mechanical shield 118 on the second major face 114 of the second circuit board 102. The control circuit can include one or more processors, such as an application processor and, optionally, one or more auxiliary processors. One or both of the application processor or the auxiliary processor(s) can be a microprocessor, a group of processing components, one or more Application Specific Integrated Circuits (ASICs), programmable logic, or other type of processing device. The application processor and the auxiliary processor(s) can be operable with the various components disposed along one or more of the first major face of the printed circuit board 104, the second major face of the first circuit board, the first major face 113 of the second circuit board 102, the second major face 114 of the second circuit board 102, the flexible substrate 105, or combinations thereof.

In one embodiment, the control circuit can be configured to process and execute executable software code to perform the various functions of the electronic device into which the circuit assembly 100 is disposed. One of the electronic components can comprise a storage device, such as memory. The memory can optionally store the executable software code used by the control circuit 117 during operation. The program instructions may alternatively be stored on-board the control circuit. The memory devices may include either or both static and dynamic memory components, may be used for storing embedded code.

In one embodiment, one electrical component comprises a near-field communication circuit configured for wireless communication with one or more other devices or networks. A chip antenna of the wireless communication circuit, which is disposed under electromagnetic shield 119, can facilitate wireless communication with the other networks or devices. The networks can include a local area network and/or personal area network. The communication circuit may utilize wireless technology for communication, such as, but are not limited to, peer-to-peer or ad hoc communications such as HomeRF, Bluetooth and IEEE 802.11 (a, b, g or n). The communication circuit can include wireless communication circuitry, one of a receiver, a transmitter, or transceiver, and one or more antennas.

One or more electromagnetic shields, e.g., electromagnetic shield 119, can be used in conjunction with the one or more electronic components. Electromagnetic shields are frequently found in radio frequency electronic devices or in other devices that may be sensitive to electromagnetic emissions. Shields are commonly used to isolate sensitive components residing on a circuit board. Electromagnetic shields are frequently made from a metal or metallized member that has a top surface and sidewalls extending orthogonally from each edge of the top surface. The bottom ends of the sidewalls may include feet or flanges so that the shield can be soldered to the circuit board.

In one embodiment, the electromagnetic shields are disposed along the major faces of the circuit boards. For example, electromagnetic shield 119 is disposed on the first major face 113 of the second circuit board 102. The electromagnetic shields can enclose one or more electronic components. In one embodiment, the electromagnetic shields are manufactured from a sheet metal frame. For example, in one embodiment, the electromagnetic shields can be machine formed from cold rolled steel. In other embodiments, the electromagnetic shields can be manufactured from cast metal. Other materials and methods of manufacture for the shield will be obvious to those of ordinary skill in the art having the benefit of this disclosure.

Electrical contacts 115,116 can be included for charging an energy storage device, such as a rechargeable battery. In this illustrative embodiment, the electrical contacts 115,116 are disposed along a bottom major face of the printed circuit board 104. In one or more embodiments, the electrical contacts 115,116 can also be used for programming the one or more electrical circuits comprising electronic components as well. For example, one or more of the electrical contacts 115,116 can be used to deliver firmware updates to the control circuit, and so forth.

In one or more embodiments, one or more microphones may be disposed on one or more of the first major face of the printed circuit board 104, the second major face of the first circuit board, the first major face 113 of the second circuit board 102, the second major face 114 of the second circuit board 102, or combinations thereof. For example, a first microphone and a second microphone, operable with the one or more electronic circuits comprising electronic components, can be disposed along the second circuit board 102. In this embodiment, the first microphone and the second microphone are disposed on the second major face 114 of the second circuit board 102, which is an opposite side the one or more electronic circuits disposed beneath electromagnetic shield 119. In one embodiment, since the first microphone and the second microphone are disposed on the bottom of the second circuit board 102, the second circuit board 102 defines one or more apertures through which the first microphone and the second microphone receive sound, respectively. In one embodiment, since the first microphone and the second microphone are disposed on the bottom side of the second circuit board 102, an acoustic porting device 120 can be disposed on the top side of the board to channel acoustic energy from an exterior housing of a device into which the circuit assembly 100 is disposed and one or both of the first microphone and the second microphone.

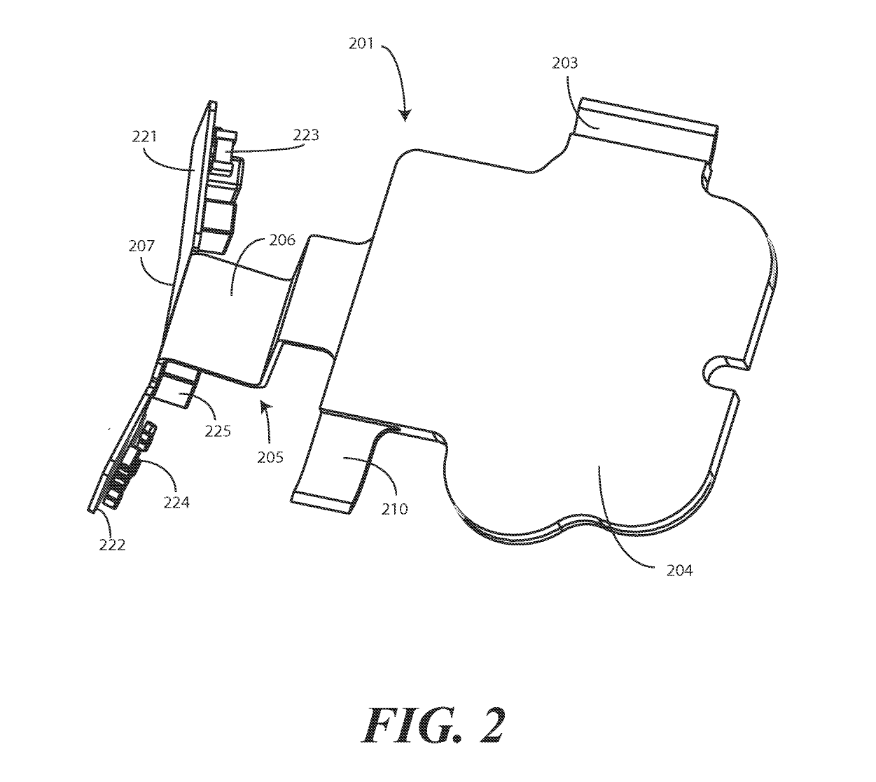

Turning now to FIG. 2, illustrated therein is a partial view of a printed circuit board assembly 201 in accordance with one or more embodiments of the disclosure. As the second flexible substrate (103) and second circuit board (102) are optional, they have been removed from the view of FIG. 2 for ease of discussion of the flexible substrate 205 extending from the printed circuit board 204. Since they can be included, a partial second flexible substrate 203 and partial third flexible substrate 210 are shown. As with the embodiment of FIG. 1, the flexible substrate 205 of FIG. 2 extends from, and is continuous with, the printed circuit board 204.

As can be seen in this embodiment, the flexible substrate 205 includes the extension portion 206, which has been folded into a double-bend chair shape in FIG. 2. The extension portion 206 then terminates at the capital portion 207, which is oriented transversely with the extension portion 206 in this embodiment. As shown in FIG. 2, in one embodiment the capital portion 207 defines a first major face 221 and a second major face 222.

In one or more embodiments, one or more electrical components 223,224 can be disposed along one or more of the first major face 221, the second major face 222, or combinations thereof. In the illustrative embodiment of FIG. 2, the one or more electrical components 223,224 are disposed along the second major face 222 of the capital portion 207 of the flexible substrate 205.

In one embodiment, the one or more electronic components 223,224 can include a sensor 225. In one embodiment, the sensor 225 is a temperature sensor to detect a rise in temperature. When the printed circuit board assembly 201 is disposed in an earbud, the temperature sensor can detect increased temperature in response to the earbud being seated in the ear. The control circuit (117) can use this increase in temperature to active and/or control the other electrical components.

In one embodiment, the sensor 225 comprises one or more infrared sensors. For example, when the printed circuit board assembly 201 is disposed in an earbud, and a housing of the earbud has a window proximately located with the infrared sensors, the infrared sensors can use a signal emitter that transmits a beam of infrared (IR) light, and then computes the distance to any nearby objects from characteristics of the returned, reflected signal. The returned signal may be detected using a signal receiver, such as an IR photodiode to detect reflected light emitting diode (LED) light, responding to modulated IR signals, and/or triangulation. When the earbud is placed within an ear, this can be detected by the infrared sensors. The control circuit (117) can use this detected infrared reflection to activate and/or control the remaining electrical components. Other proximity sensor components can be substituted for the infrared sensors, such as but not limited to, capacitive, magnetic, inductive, optical/photoelectric, laser, acoustic/sonic, radar-based, Doppler-based, thermal, and radiation-based proximity sensors.

Disposing the infrared sensor along the capital portion 207 of the flexible substrate 205 extending from the printed circuit board 204 has distinct advantages. False detection of an ear is greatly reduced when the infrared sensor is disposed within an ear canal insertion stem of an ear bud housing. By placing the infrared sensor or temperature along the capital portion 207 of the flexible substrate 205, this can occur, thereby reducing false ear detection. Additionally, disposing the infrared sensor—and the other one or more electrical components 223,224—along the capital portion 207 of the flexible substrate 205 extending from the printed circuit board 204 frees up real estate along the printed circuit board 204.

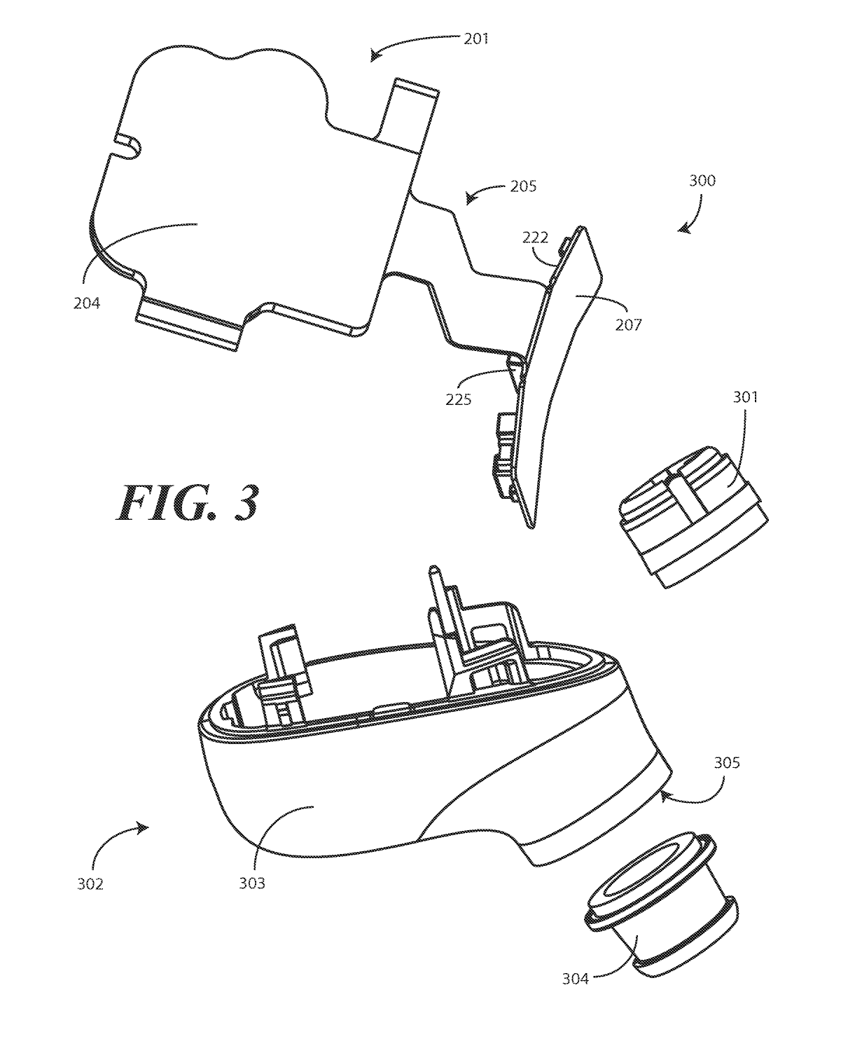

Turning now to FIG. 3, illustrated therein is one explanatory assembly 300 in accordance with one or more embodiments of the disclosure. Shown in FIG. 3 is the partial view of the printed circuit board assembly 201 from FIG. 2, an acoustic driver 301, and a partial ear bud housing 302. The ear bud housing 302 includes a body 303 and an ear canal insertion stem 304, which attaches to an acoustic opening 305 of the ear bud housing 302.

In one embodiment, the acoustic driver 301 comprises a balanced armature speaker. The acoustic driver 301 can be electrically coupled to the printed circuit board 204 of the printed circuit board assembly 201. The acoustic driver 301 is a speaker in one embodiment that will serve as the acoustic output of the assembly 300 that delivers sound through the ear canal insertion stem 304 to a user's eardrum.

The challenge with this assembly 300 is that the sensor 225 attached to the second major face 222 of the capital portion 207 of the flexible substrate 205 needs to be inserted into the ear canal insertion stem 304 for optimal detection of when the ear bud housing 302 is inserted into a user's ear. However, in one or more embodiments, the acoustic driver 301 is disposed in the body 303 of the ear bud housing 302, i.e., above the capital portion 207 of the flexible substrate 205. If assembling the assembly 300 by hand, the capital portion 207 of the flexible substrate 205 extending from the printed circuit board 204 can collapse within the ear canal insertion stem 304, thereby occluding the ear canal insertion stem 304 and preventing acoustic energy from the acoustic driver 301 from passing through the ear canal insertion stem 304 to a user's eardrum.

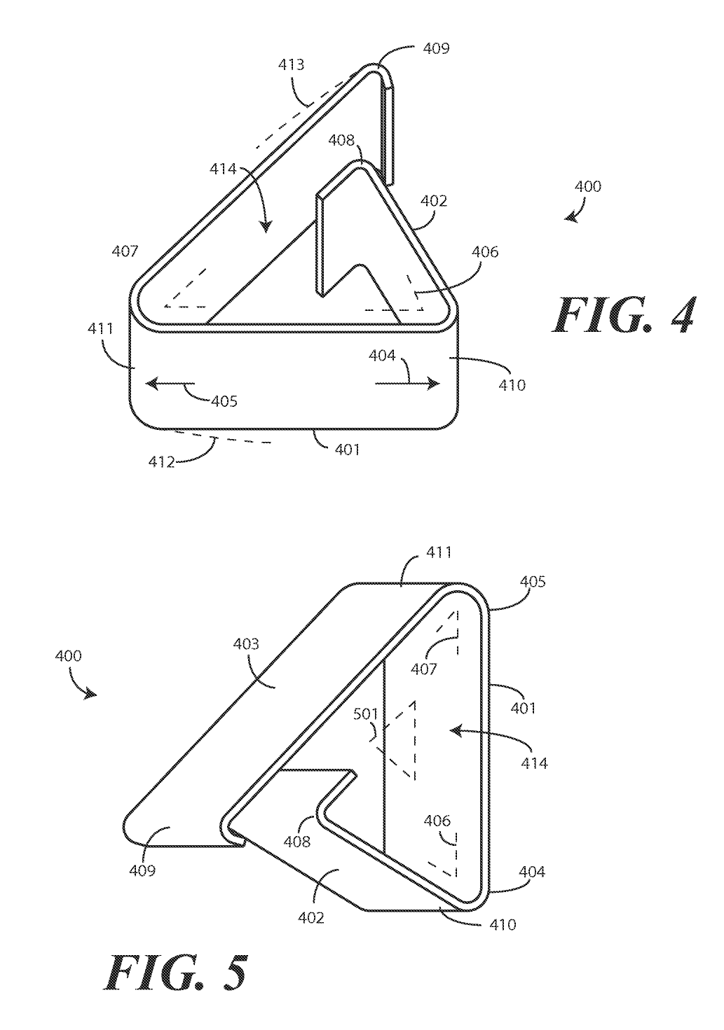

Turning now to FIGS. 4 and 5, illustrated therein is the solution to this problem. Illustrated in FIGS. 4-5 is a spring member 400. The spring member 400 can be manufactured from a variety of materials, including metals, thermoplastics and resins. In one or more embodiments, the spring member 400 is manufactured from a springy material, such as springy steel or springy plastic. In the illustrative embodiment of FIGS. 4-5, the spring member 400 is manufactured from a unitary piece of springy metal. Other materials suitable for manufacturing the spring member 400 will be obvious to those of ordinary skill in the art having the benefit of this disclosure.

In one embodiment the springy metal is formed about a tool to create the resulting shape of the spring member 400. Where so manufactured, the result can be referred to as a spring form. In the illustrative embodiment of FIGS. 4-5, the spring form includes a base member 401, a first spring arm 402, and a second spring arm 403. In this illustrative embodiment, the first spring arm 402 extends distally from a first side 404 of the base member 401 at a first acute angle 406. Similarly, the second spring arm 403 extends distally from a second side 405 of the base member 401 at a second acute angle 407. This results in the spring member 400 having a triangular cross section 501 in one embodiment. While the triangular cross section 501 is one example of what shape the spring member 400 can take, others will be obvious to those of ordinary skill in the art having the benefit of this disclosure. For example, the spring member 400 can be formed to have a square cross section, a pentagonal cross section, a hexagonal cross section, or other cross section.

In one embodiment, the triangular cross section 501 defines an acoustic duct 414 through which acoustic energy may pass. For example, if the spring member 400 were placed between the acoustic driver (301) and a port of the ear canal insertion stem (304), acoustic energy from the acoustic driver (301) could flow through the acoustic channel 404 to the port of the ear canal insertion stem (304) for delivery to a user's eardrum.

In one embodiment, the triangle defined by the spring member 400 is an incomplete triangle in that the first spring arm 402 and the second spring arm 403 to not intersect at ends distally disposed from the base member 401. This is by design in one embodiment, as one or more of the first spring arm 402 or the the second spring arm 403 are configured to deflect relative to the base member 401 with the spring member 400 is inserted into an ear canal insertion stem (304) of an ear bud device.

In one embodiment, the first spring arm 402 and the second spring arm 403 have different lengths. For example, in the illustrative embodiment of FIGS. 4-5 the second spring arm 403 is longer than the first spring arm 402. In such an embodiment, the longer spring arm can be configured to deflect relative to the base member 401 with the spring member 400 is inserted into an ear canal insertion stem (304) of an ear bud device, while the shorter spring arm can remain undeflected.

In in one or more embodiments, the first spring arm 402 and the second spring arm 403 each terminate at radiused bends. For example, in this embodiment the first spring arm 402 terminates at a first radiused bend 408, while the second spring arm 403 terminates at a second radiused bend 409. The inclusion of the radiused bends provides smooth, curved surfaces to engage the inner surfaces of an ear canal insertion stem (304) when the spring member 400 is used in an ear bud.

In the illustrative embodiment of FIGS. 4-5, the corners 410,411 defined between the base member 401 and first spring arm 402, and the base member 401 and second spring arm 403, respectively, are also radiused. For example, in one embodiment the corner 410 defined between the base member 401 and first spring arm 402 defines a third radiused bend. Similarly, in one embodiment the corner 411 defined by the base member 401 and second spring arm 403 defines a fourth radiused bend. As with the first radiused bend 408 and the second radiused bend 409, the third radiused bend and fourth radiused bend can provide smooth, curved surfaces to engage the inner surfaces of an ear canal insertion stem (304) when the spring member 400 is used in an ear bud.

In one embodiment, when the spring member 400 is inserted into an ear canal insertion stem (304) of an ear bud housing (302), the second radiused bend 409, the third radiused bend at corner 410, and the fourth radiused bend at corner 411 engage the inner surfaces of a ear canal insertion stem (304). When this occurs, one or more of the base member 401 or the second spring arm 403 are to deflect 412,413 to apply a biasing force against the inner surface of the ear canal insertion stem (304). This deflection causes the acoustic duct 414 to expand, thereby precluding any blockage of the acoustic energy.

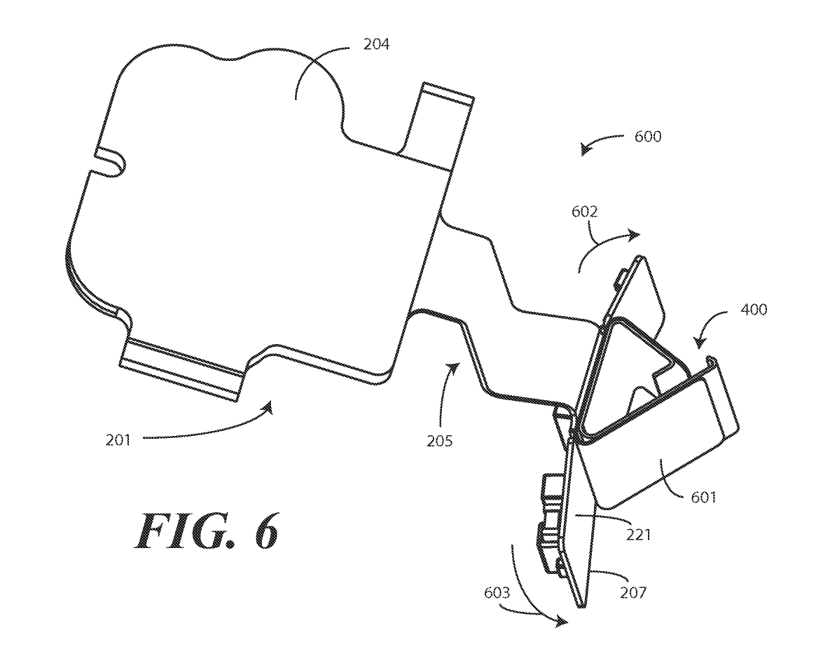

Turning now to FIG. 6, illustrated therein is a circuit assembly 600 configured in accordance with one or more embodiments of the disclosure. The circuit assembly 600 of FIG. 6 includes the printed circuit board assembly 201 of FIG. 2 and the spring member 400 of FIG. 4. Also included in this illustrative embodiment is an adhesive layer 601 disposed about the spring member 400.

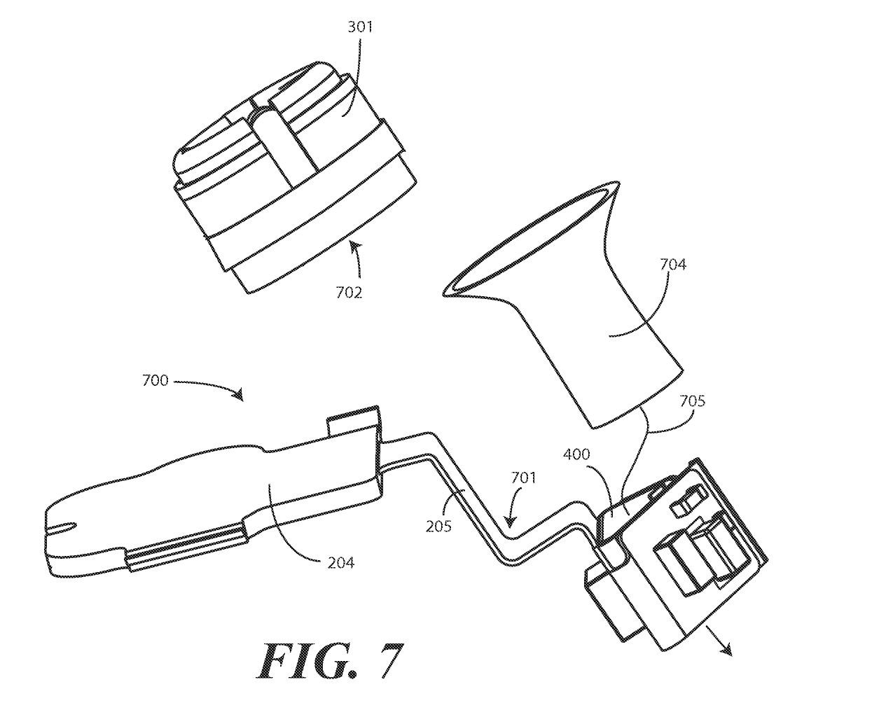

In one embodiment, the first major face 221 of the capital portion 207 of the flexible substrate 205 extending from, and continuous with, the printed circuit board 204, is wrapped 602,603 about the spring member 400. In the illustrative embodiment of FIG. 6, the capital portion 207 is adhesively coupled to the exterior sides of the spring member 400 with the adhesive layer 601. The resulting assembly 700 is shown in FIG. 7.

In one or more embodiments, once the assembly 700 is constructed, the acoustic driver 301 can be electrically coupled to the printed circuit board 204. As noted above, the acoustic driver 301 can be configured as a speaker that will serve as the acoustic output of the assembly 700. Once coupled to the printed circuit board 204, the acoustic driver 301 will be positioned at a bend 701 of the flexible substrate 205. Depending upon how compact the assembly 700—or the resulting ear bud device—will be, the bend 701 can approach an orthogonal angle. Where this is the case, some acoustic leakage can occur between the output 702 of the acoustic driver 301 and the flexible substrate 205. While this leakage is generally minimal and acceptable in most applications, in some low power applications all acoustic leakage should be reduced as much as possible. Additionally, in some compact designs acoustic leakage could allow acoustic energy to flow into the assembly 700 to a microphone, thereby making echo and/or noise suppression more difficult.

Accordingly, in one or more embodiments audio from the acoustic driver 301 can be ported through the center of the spring member 400 through a funnel-shaped tube 704. In one embodiment, the funnel-shaped tube 704 comprises a flexible, plastic tube that is placed 705 through the spring member 400 with one end sealed against the acoustic driver 301. This configuration allows the flexible substrate 205 to pass along the outside of the funnel-shaped tube 704 without causing acoustic leakage. The funnel-shaped tube 704 is optional. In one embodiment, the funnel-shaped tube 704 comprises a separate part, adhered to the acoustic driver 301 to ensure no acoustic leakage occurs.

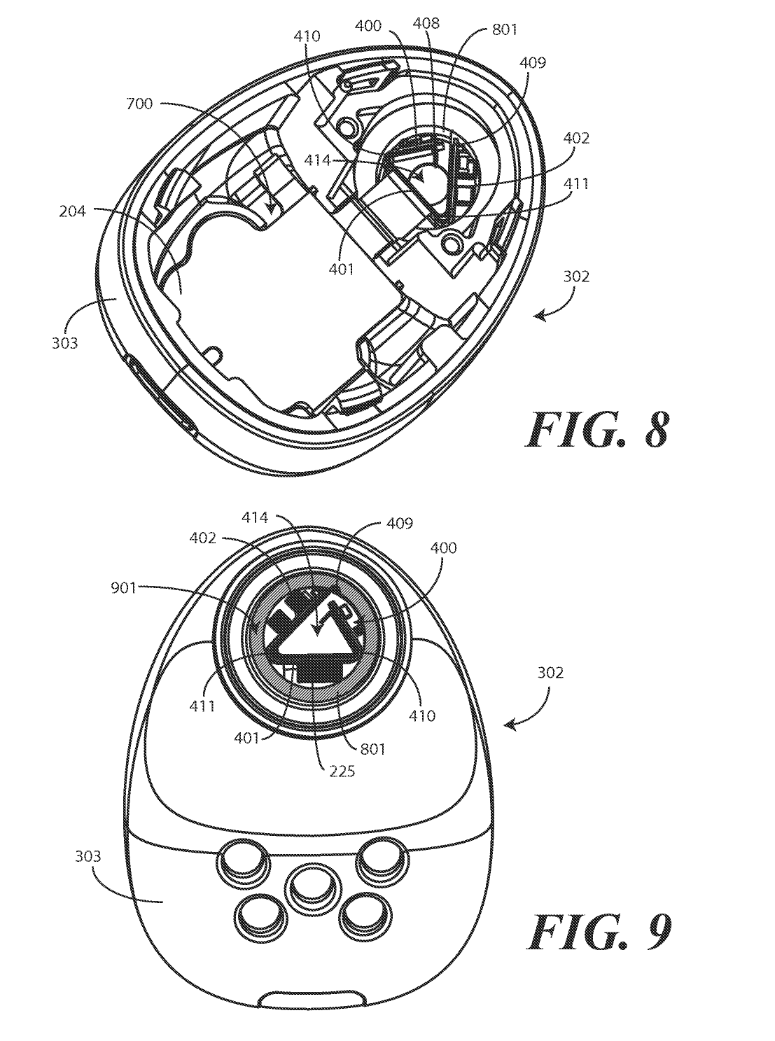

Turning now to FIGS. 8 and 9, the assembly 700 has been inserted into an ear bud housing 302 with the spring member 400 inserted into the ear canal insertion stem 304 and the printed circuit board 204 disposed within the body 303 of the ear bud housing 302. A top view is shown in FIG. 8, while the port 901 of the ear canal insertion stem 304 can be seen in the bottom view of FIG. 9.

As can be seen, in this illustrative embodiment the second radiused bend 409, the third radiused bend at corner 410, and the fourth radiused bend at corner 411 engage the inner surface 801 of the ear canal insertion stem 304. When this occurs, one or more of the base member 401 or the second spring arm 403 are to deflect (412,413) to apply a biasing force against the inner surface 801 of the ear canal insertion stem 304. This deflection causes the acoustic duct 414 to expand, thereby precluding any blockage of the acoustic energy from any acoustic driver placed above the spring member 400. Additionally, the rigidity of the spring member 400 makes insertion into the ear canal insertion stem 304 quick and easy. Advantageously, the sensor 225 can also be disposed in the ear canal insertion stem 304 without blocking acoustic energy passing through the acoustic duct 414 from the acoustic driver to the port 901.

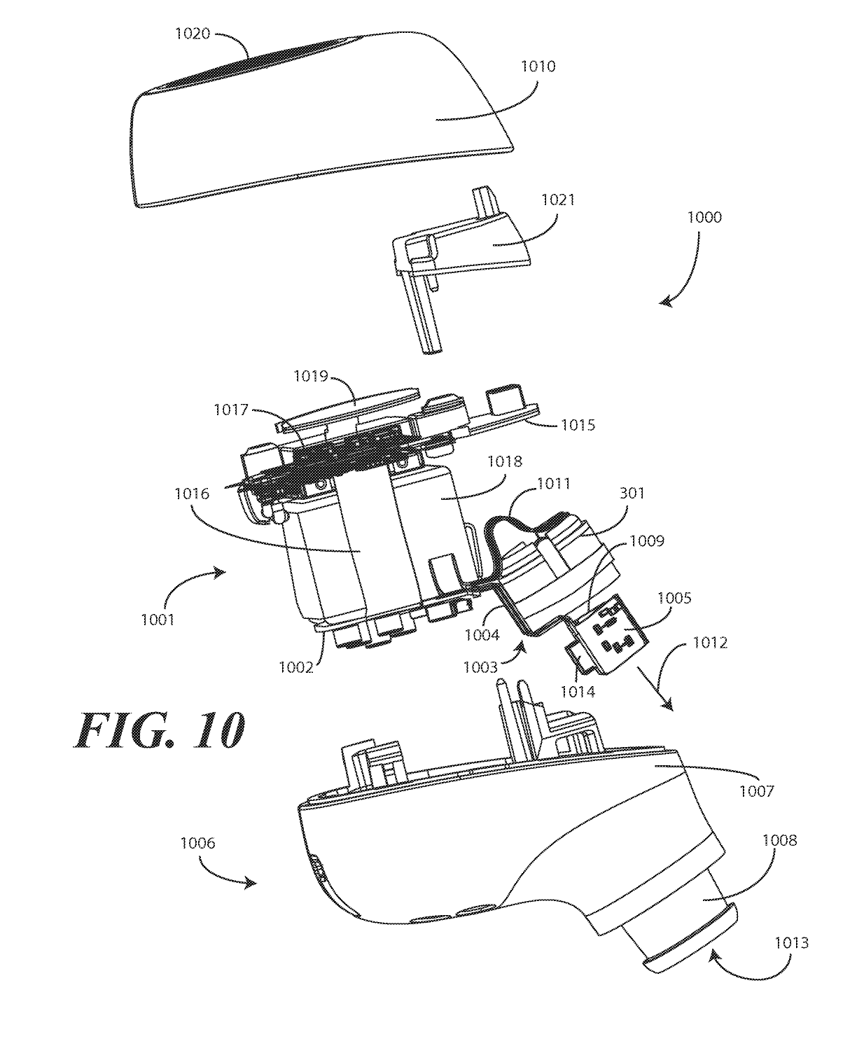

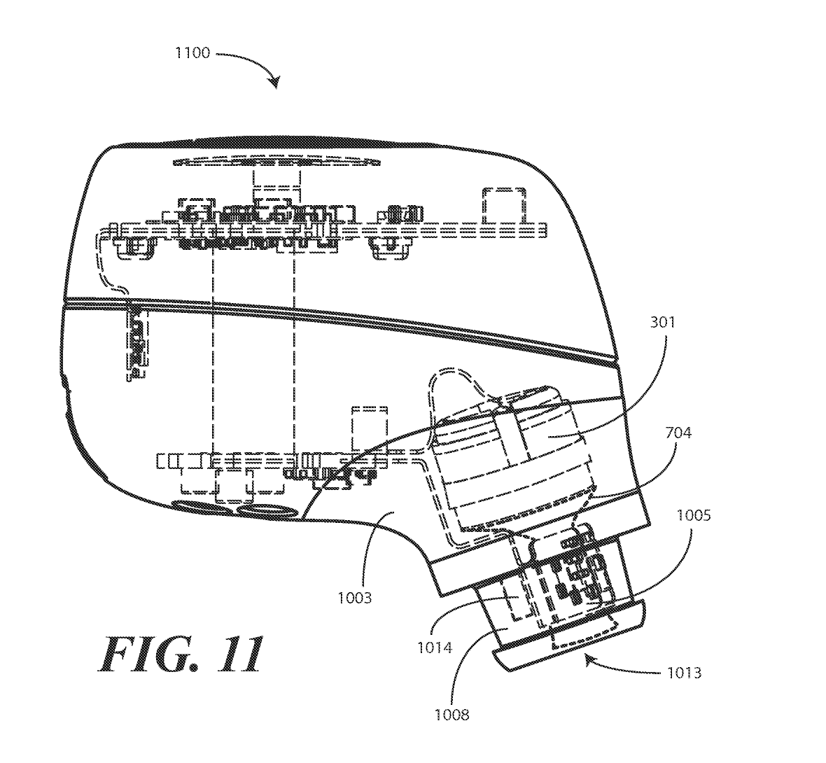

Turning now to FIG. 10, illustrated therein is another assembly 1000 configured in accordance with one or more embodiments of the disclosure. The assembly 1000 of FIG. 10 includes a unitary printed circuit board assembly 1001 comprising a printed circuit board 1002 and a flexible substrate 1003 extending from, and continuous with, the printed circuit board 1002. In this illustrative embodiment, the flexible substrate 1003 comprises a first portion 1004 extending from the printed circuit board 1002 and terminating a second portion 1005. In this illustrative embodiment, the second portion 1005 is transversely oriented with the first portion 1004, and has been wrapped about a spring form 1009. An infrared sensor 1014 is coupled to the second portion 1005 of the flexible substrate 1003 so that it can be inserted into the ear insertion stem 1008.

A lower housing 1006 defines a body 1007 and an ear insertion stem 1008. The spring form 1009 supporting the second portion 1005 of the flexible substrate 1003 is to be disposed within the ear insertion stem 1008 as described with reference to FIGS. 8-9 above. In one embodiment, when this occurs arms of the spring form 1009 applying a biasing force against inner surfaces of the ear insertion stem 1008.

An acoustic driver 301 is disposed along the first portion 1004 of the flexible substrate 1003 and is electrically coupled to the printed circuit board 1002 by a pair of wire leads 1011. As with previous embodiments, the spring form 1009 defines an acoustic port 1021 to direct acoustic energy from the acoustic driver 301 to a port 1013 of the ear insertion stem 1008.

As with the embodiment of FIG. 1, the unitary printed circuit board assembly 1001 of FIG. 10 also includes a second circuit board 1015. A second flexible substrate 1016 is interposed between, and is continuous with, the printed circuit board 1002 and the second circuit board 1015. The inclusion of the second flexible substrate 1016 as a continuous element between the printed circuit board 1002 and the second circuit board 1015 advantageously allows unitary printed circuit board assembly 1001 to fold or otherwise be wrapped around components.

For example, in this illustrative embodiment the electrical components 1017 of the assembly 1000 are powered by a battery 1018. Here the printed circuit board 1002, the second circuit board 1015, and the second flexible substrate 1016 are folded to form a “C” shape about the battery 1018. In one embodiment, an insulating layer (not shown) can be disposed between the battery 1018 and either printed circuit board to electrically isolate any electrical components disposed on the printed circuit board from terminals of the battery 1018. The insulating layer can be manufactured from an insulating material such as Kapton.sup™. Other insulating materials suitable for the insulating layer will be obvious to those of ordinary skill in the art having the benefit of this disclosure.

In this illustrative embodiment, the unitary printed circuit board assembly 1001 also includes third flexible substrate 1019. In this illustrative embodiment, the third flexible substrate 1019 is folded back over the second circuit board 1015 so as to be used as a touch sensor disposed just beneath a surface of an upper housing 1010 of the assembly 1000, thereby eliminating the need for buttons or other controls that, when actuated, may move the ear bud within the user's ear. Other optional components, such as an acoustic port 1021 can be included as well.

When the upper housing 1010 and the lower housing 1006 are then coupled together, the resulting assembly 1100 is shown in FIG. 11. The various components of FIG. 10 are shown in dashed line so that their respective locations can be seen. As shown in FIG. 11, the second portion 1005 of the flexible substrate is wrapped about the spring form 1009, and inserted into the ear insertion stem 1008. The infrared sensor 1014 is therefore disposed in the ear insertion stem 1008. The spring form 1009 is thus disposed between the acoustic driver 301 and the port 1013 of the ear insertion stem 1008. As the spring form 1009 defines an acoustic duct, acoustic energy is passed from the acoustic driver 301 to the port 1013 of the ear insertion stem 1008 to the eardrum of a user. Meanwhile, the infrared sensor 1014 is optimally positioned to detect the assembly 1100 being inserted into an ear without obstructing acoustic energy or compromising acoustic performance. In this illustrative embodiment, the optional funnel-shaped tube 704 is also positioned between the acoustic driver 301 and the port 1013 of the ear insertion stem 1008 to direct sound through the center of the spring form 1009.

As described, embodiments of the disclosure provide for a compact device, such as assembly 1100, suitable for use in a person's ear, that employs a printed circuit board assembly comprising rigid circuit boards having continuous flexible substrates extending therefrom or interspaced therebetween. The printed circuit board assembly can be folded about a battery to provide a compact, low profile, and high-performance circuit assembly. Flexible substrates can be wrapped about spring forms or spring members so that sensors, like infrared sensors, can be placed within an ear insertion stem without compromising acoustic performance. Embodiments of the disclosure advantageously integrate and optimize of a number of mechanical and electrical devices and elements to deliver a compact design for an in-ear device.

In the foregoing specification, specific embodiments of the present disclosure have been described. However, one of ordinary skill in the art appreciates that various modifications and changes can be made without departing from the scope of the present disclosure as set forth in the claims below. Thus, while preferred embodiments of the disclosure have been illustrated and described, it is clear that the disclosure is not so limited. Numerous modifications, changes, variations, substitutions, and equivalents will occur to those skilled in the art without departing from the spirit and scope of the present disclosure as defined by the following claims. Accordingly, the specification and figures are to be regarded in an illustrative rather than a restrictive sense, and all such modifications are intended to be included within the scope of present disclosure. The benefits, advantages, solutions to problems, and any element(s) that may cause any benefit, advantage, or solution to occur or become more pronounced are not to be construed as a critical, required, or essential features or elements of any or all the claims.

What is claimed is:

1. A circuit assembly, comprising:
a printed circuit board assembly, comprising:
a circuit board;
a flexible substrate extending from, and continuous with, the circuit board, the flexible substrate comprising an extension portion terminating at a capital portion; and
a spring member;
the capital portion wrapped about the spring member.

2. The circuit assembly of claim 1, the capital portion defining a first major face and a second major face, the first major face disposed adjacent to sides of the spring member, and one or more electronic circuits disposed on the second major face.

3. The circuit assembly of claim 2, the first major face adhesively coupled to the sides of the spring member.

4. The circuit assembly of claim 1, the spring member comprising:
a base member;
a first spring arm extending distally from a first side of the base member at a first acute angle; and
a second spring arm extending distally from a second side of the base member at a second acute angle.

5. The circuit assembly of claim 4, the spring member manufactured from a unitary piece of springy metal.

6. The circuit assembly of claim 4, the spring member defining an acoustic duct between the base member, the first spring arm, and the second spring arm.

7. The circuit assembly of claim 4, the base member, the first spring arm, and the second spring arm defining a triangular cross section of the spring member.

8. The circuit assembly of claim 4, further comprising an ear bud housing comprising a body and an ear canal insertion stem, one or more of the base member or the second spring arm to deflect to apply a biasing force against an inner surface of the ear canal insertion stem.

9. The circuit assembly of claim 8, the first spring arm terminating at a first radiused bend, the second spring arm terminating at a second radiused bend.

10. The circuit assembly of claim 9, the spring member comprising:
a third radiused bend between the base member and the first spring arm; and
a fourth radiused bend between the base member and the second spring arm.

11. The circuit assembly of claim 10, the second radiused bend and the fourth radiused bend to engage the inner surface of the ear canal insertion stem to deflect the second spring arm.

12. The circuit assembly of claim 8, the ear canal insertion stem extending from the body and terminating at a port, further comprising an acoustic driver, the spring member disposed between the acoustic driver and the port.

13. The circuit assembly of claim 12, the acoustic driver to deliver acoustic energy through the spring member to the port.

14. The circuit assembly of claim 12, further comprising a second circuit board and a second flexible substrate interposed between, and continuous with the circuit board and the second circuit board, the circuit board, the second circuit board, and the second flexible substrate folded in a C-shape.

15. The circuit assembly of claim 1, the extension portion and the capital portion defining an inverted T-shape.

16. An assembly, comprising:
a unitary printed circuit board assembly comprising a circuit board and a flexible substrate extending from, and continuous with, the circuit board, the flexible substrate comprising a first portion extending from the circuit board and terminating a second portion transversely oriented with the first portion;
a spring form;
the second portion of the flexible substrate wrapped about the spring form; and
a housing defining a body and an ear insertion stem;
the spring form disposed within the ear insertion stem with arms of the spring form applying a biasing force against inner surfaces of the ear insertion stem.

17. The assembly of claim 16, further comprising an acoustic driver disposed along the first portion of the flexible substrate.

18. The assembly of claim 17, the spring form defining an acoustic channel to direct acoustic energy from the acoustic driver to a port of the ear insertion stem.

19. The assembly of claim 18, the spring form defining a triangular cross section.

20. The assembly of claim 16, further comprising an infrared sensor coupled to the second portion of the flexible substrate.
